(19) United States
(12) Patent Application Publication
(10) Pub. No.: US 2018/0067227 A1
(43) Pub. Date: Mar. 8, 2018

(54) LIGHT CURTAIN

(71) Applicant: SICK AG, Waldkirch (DE)

(72) Inventors: Johannes EBLE, Waldkirch (DE); Sebastian MATT, Waldkirch (DE)

(21) Appl. No.: 15/697,488

(22) Filed: Sep. 7, 2017

(30) Foreign Application Priority Data
Sep. 8, 2016 (DE) 102016116835.1
Aug. 4, 2017 (DE) 102017117693.4

(51) Int. Cl. G01V 8/20; F21V 15/01; G01V 8/16; H05K 1/14

(52) U.S. Cl. CPC G01V 8/20; H05K 1/148; G01V 8/16; F21V 15/01

(57) ABSTRACT

A light curtain having at least two electronic cards which are arranged behind one another and on which a plurality of light transmitters and/or light receivers are arranged in series, wherein the electronic cards are each connected to one another by a mechanical connection element and the electronic cards are held in a housing, wherein the housing is formed as a profile housing, wherein the first electronic card and the last electronic card are fixed to the respective housing end in the longitudinal direction so that the last light transmitter and/or light receiver of the first electronic card and of the last electronic card, said last light transmitter and/or light receiver contacting the housing end, has a fixed defined spacing from the housing end, and wherein the connection element has a minimal spacing and a maximum spacing between the electronic cards.

The present invention relates to a light curtain in accordance with the preamble of claim 1.

Light curtains typically have a series of electronic cards or printed circuit boards on which transmission elements or transmission optics modules or reception optics modules are arranged. This series of electronic cards is also called a chain. This chain is fixed in a housing composed of metal or plastic, for example at an end. Light curtains are specified over a large temperature range, in part larger than ΔT=100° C., and should also reach this performance in this total range.

The electronic card is produced from the material FR-4, for example. FR-4 or also FR4 specifies a class of flame-resistant and flame-retardant composite material comprising epoxy resin and glass fiber fabric. The abbreviation FR stands for “flame retardant” and corresponds to the requirement of UL94V-0.

FR-4 is inter alia used as an electrically non-conductive carrier material for electrical electronic cards or printed circuit boards. FR-4 has good creep resistance and small water absorption. A further advantage of FR-4 is its good adhesion capability that ensures a permanent application of conductor tracks of composed of copper on the carrier material.

The electronic card material FR-4, however, has a different temperature-dependent coefficient of expansion than the housing materials of metal and plastic. If the electronic cards were to be set up in a manner fixed relative to one another and fastened to one housing end, the second or opposite end of the chain would move relative to the second housing end on temperature changes. The spacing of the last light transmitters and/or light receivers from the housing end would vary, with a co-called blind region varying up to the housing end.

An additional spacing moreover has to be observed in order, on the one hand, to ensure an expansion of the optics chain in the housing and, on the other hand, to take up tolerances in the optical chain and in the housing.

In accordance with the prior art, the non-fastened end of the chain moves relative to the housing end in dependence on the temperature so that the spacing between the light transmitter and/or the light receiver at the end of the housing and the housing is changed, whereby a detection of objects cannot always be ensured.

It is an object of the invention to also generate a resolution of a light curtain at the marginal regions on temperature changes.

The object is satisfied in accordance with claim 1 by a light curtain having at least two electronic cards which are arranged behind one another in a longitudinal direction and on which a plurality of light transmitters and/or light receivers are arranged in series, wherein the electronic cards are each connected to one another by a mechanical connection element and the electronic cards are held in a housing, wherein the housing is configured as a profile housing, wherein the first electronic card and the last electronic card are fixed to the respective housing ends in the longitudinal direction so that the last light transmitter and/or light receiver of the first electronic card and of the last electronic card, said last light transmitter and/or light receiver contacting the housing end, has a fixedly defined spacing from the housing end, wherein the connection element bounds a minimal spacing and a maximum spacing between the electronic cards, and wherein the maximum spacing is larger than the minimal spacing.

The light curtain has the advantage that the first light transmitter and/or a light receiver is/are locally stable relative to the housing start and the last light transmitter and/or light receiver is/are locally stable relative to the housing end. The light curtain thus has a constant blind region. The light curtain can, for example, also be cascaded and a grid spacing of the cascaded light transmitters and/or light receivers can simultaneously be ensured.

At least two electronic cards or printed circuit boards are arranged in the light curtain in this respect. The fixing of the end-side electronic cards can take place directly, for example, via a hole in the electronic card and in a fixing element in the housing or housing end piece or indirectly via an additional part that connects the electronic card to the housing or to the housing end piece. The first or last light transmitters or light receivers thus also have the same spacing from the housing end on temperature changes.

A spacing is formed between the electronic cards by the mechanical connection element so that the electronic cards have maximum contact with a maximum temperature change and with worst case tolerances.

If three or more electronic cards are used, the electronic cards not disposed at the ends of the housing have a specific clearance in dependence on the temperature and on the tolerances present to move along the light curtain. The more electronic cards that are used, the greater the largest possible gap will be at a position, namely when all the electronic cards except for a fixed electronic card at the end were to be pushed together. This gap would degrade the resolving power of the light curtain since the resolution is primarily determined by the spacing of the light transmitters from one another or the spacing of the light receivers from one another.

The mechanical connection element has mechanical elements which bound a maximum spacing between two electronic cards. The mechanical connection element furthermore has mechanical elements that bound a minimal spacing between the electronic cards.

The maximum spacing is larger than the minimal spacing. The maximum spacing and the minimum spacing are thus not identical.

The minimal and maximum spacings between the electronic cards are formed, for example, by elongate holes in the electronic cards and in the mechanical connection element that is not variable in length, with the mechanical connection element being connected by pins to the elongate holes of the electronic card. The elongate hole together with the pin of the mechanical connection element defines the minimal and maximum spacings of the electronic cards.

A small blind region and its guaranteed size have the result that the light curtain can be installed flush at surfaces and can thus be measured close to these surfaces.

The light curtain can thereby also be used in a space-saving manner since the total length of the light curtain is usable.

In a further development of the invention, the connection element is connected to the electronic card in one piece.

The ensuring of the minimal and maximum spacing between the electronic cards is in this respect directly formed, for example, via a contour in the electronic card. For this purpose, the electronic cards are, for example, guided in a groove of the housing.

In a preferred embodiment of the invention, the connection element has at least one spring element.

The spring element provides that the electronic cards are mutually pre-loaded. In this process, the springs are, for example, formed as tension springs or compression springs. In the case of tension springs, the electronic cards are pulled toward one another and in the case of compression springs, the electronic cards are repelled from one another. The spacing between the electronic cards is, however, preset in a defined manner by the spring elements so that there is practically no clearance, for example due to a movement, for example a vibration/shock load.

The mechanical connection element can also be formed in two parts. The spring elements can, for example, be formed as a separate part or can be integrated in the mechanical connection element.

In a further development of the invention, the connection element has at least two spring elements, with the spring elements having different spring constants.

On a vibration excitation of the light curtain, the light curtain is then more resistant since there is no individual defined resonant frequency.

The invention will also be explained in the following with respect to further advantages and features with reference to the enclosed drawing and to embodiments. The Figures of the drawing show in:

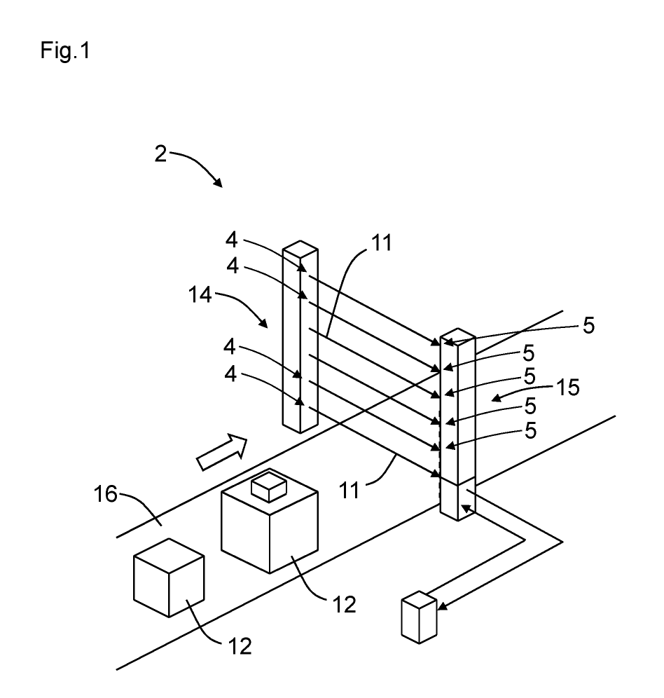

FIG. 1 a light curtain at a conveying belt;

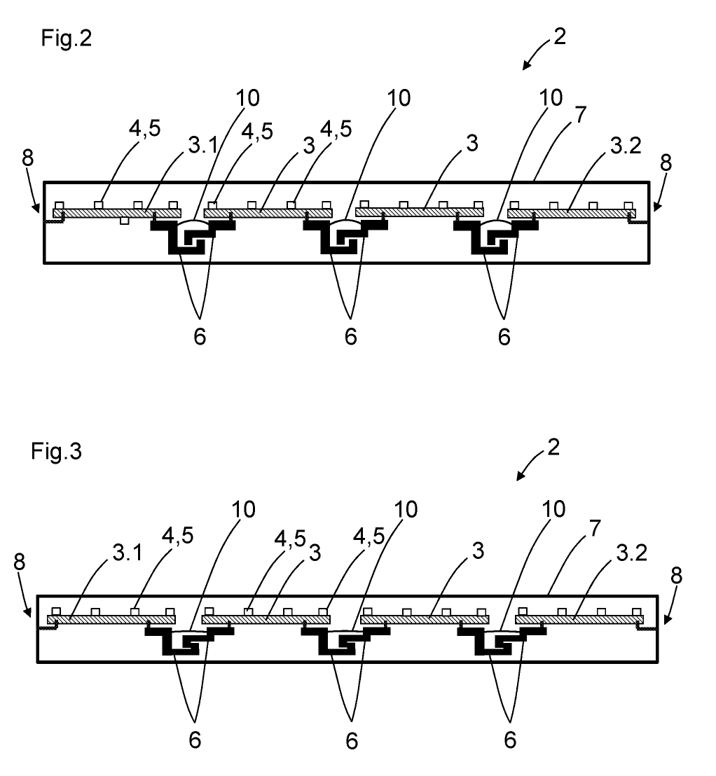

FIGS. 2 to 4 respectively, a light curtain with electronic cards and mechanical connection elements;

FIG. 5 two electronic cards; and

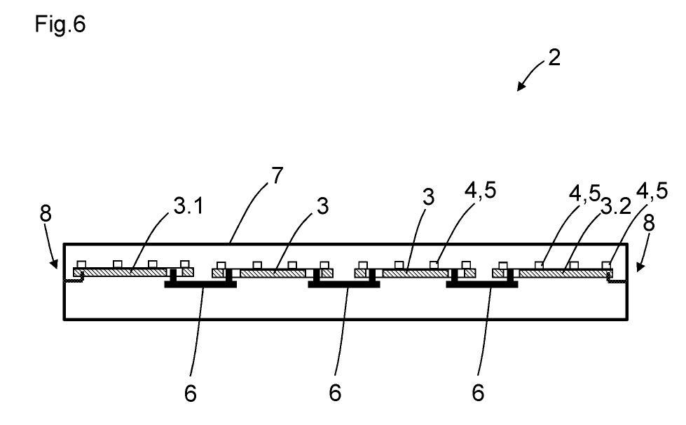

FIG. 6 a light curtain with electronic cards and mechanical connection elements.

In the following Figures, identical parts are provided with identical reference numerals.

FIG. 1 shows a light curtain 2 for measuring objects 12 and/or for monitoring a hazardous zone of a machine comprising a transmission unit 14 having a plurality of light transmitters 4 emitting light beams 11 and having a reception unit 15 having a plurality of light receivers 5 receiving light beams 13 to detect the objects 12. A control and evaluation unit is furthermore provided that is configured to generate a measurement signal, for example for the machine, on a detection of an object 12, wherein the control and evaluation unit is configured to output data on the object 12, for example the object height and/or the object dimensions, on a detection of an object 12.

The light curtain is directly arranged above a conveyor belt 16 in accordance with FIG. 1 so that a spacing between the light beam 11 and the conveyor belt 16 is minimal. The spacing between the last light beam 11 and the conveyor belt 16 is also called a blind region. A small blind region and its guaranteed size have the result that the light curtain can be installed flush at surfaces and can thus be measured close to these surfaces. The light curtain 2 can thereby also be used in a space-saving manner since the total length of the light curtain 2 is usable.

FIG. 2 shows a light curtain 2 having at least two electronic cards 3 which are arranged behind one another and on which a plurality of light transmitters 4 and/or light receivers 5 are arranged in series, wherein the electronic cards 3 are each connected to one another by a mechanical connection element 6 and the electronic cards are held in a housing 7, wherein the housing 7 is formed as a profile housing, wherein the first electronic card 3.1 and the last electronic card 3.2 are fixed to the respective housing end 8 in the longitudinal direction so that the last light transmitter 4 and/or light receiver 5 of the first electronic card 3.1 and of the last electronic card 3.2, said last light transmitter and/or light receiver contacting the housing end 8, has a fixed defined spacing from the housing end 8, and wherein the connection element 6 has a minimal spacing and a maximum spacing between the electronic cards 3. The maximum spacing is larger than the minimal spacing in this respect.

At least two electronic cards 3 or printed circuit boards are arranged in the light curtain 2 in this respect. In accordance with FIG. 2, four electronic cards are arranged.

A fixing of the end-side electronic cards 3.1 and 3.2 can take place directly, for example, via a hole in the electronic card 3 and in a fixing element in the housing 7 or housing end piece or indirectly via an additional part that connects the electronic card 3 to the housing 7 or to the housing end piece. The first or last light transmitters 4 or light receivers 5 thus also have the same spacing from the housing end on temperature changes.

A spacing is formed between the electronic cards 3 by the mechanical connection element 6 so that the electronic cards 3 have maximum contact with a maximum temperature change and with worst case tolerances.

If three or more electronic cards 3 are used, the electronic cards 3 not disposed at the ends of the housing have a specific clearance in dependence on the temperature and on the tolerances present to move along the light curtain. The more electronic cards 3 that are used, the greater the largest possible gap will be at a position, namely when all the electronic cards 3 except for a fixed electronic card 3 at the end were to be pushed together. This gap would degrade the resolving power of the light curtain 2 since the resolution is primarily determined by the spacing of the light transmitters 4 from one another or the spacing of the light receivers 5 from one another.

The mechanical connection element 6 has mechanical elements which bound a maximum spacing between two electronic cards 3. The mechanical connection element 6 furthermore has mechanical elements that bound a minimal spacing between the electronic cards 3.

In accordance with FIG. 2, the connection element 6 has at least one spring element 10. The spring element 10 provides that the electronic cards 3 are mutually pre-loaded. In this process, the springs are, for example, formed as tension springs or compression springs. In the case of tension springs, the electronic cards 3 are pulled toward one another and in the case of compression springs, the electronic cards 3 are repelled from one another. The spacing between the electronic cards 3 is, however, preset in a defined manner by the spring elements 10 so that there is practically no clearance.

The mechanical connection element 6 can also be formed in two parts. The spring elements 10 can, for example, be formed as separate parts or can be integrated in the mechanical connection element.

In accordance with FIG. 2, the light curtain is shown with the optics chain comprising the mounted electronic cards 3 and the mechanical connection elements 6 at a normal temperature of, for example, 20 degrees Celsius. The spring elements 10 are shown in a relaxed state.

FIG. 3 shows the light curtain of FIG. 2 at a maximum temperature. The spring elements 10 are negatively loaded or are acted on by a tensile force The mechanical elements of the mechanical connection element are shown at the position of maximum spacing.

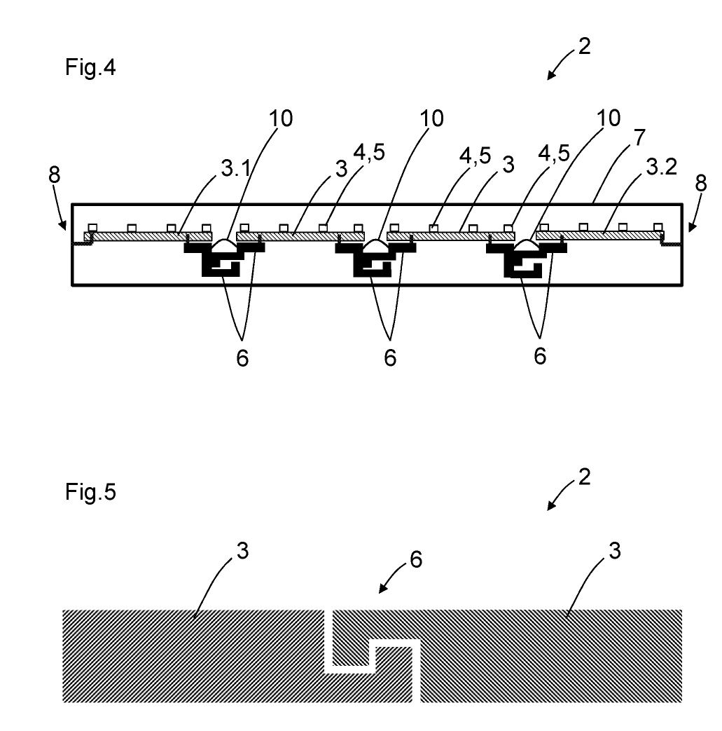

FIG. 4 shows the light curtain of FIG. 2 at a minimal temperature. The spring elements 10 are positively loaded or are acted on by a compression force. The mechanical elements of the mechanical connection element are shown at the position of minimal spacing.

In accordance with FIG. 5, the mechanical connection element 6 is connected to the electronic card 3 in one piece. The ensuring of the minimal and maximum spacing between the electronic cards 3 is in this respect directly formed, for example, via a contour in the electronic card 3. For this purpose, the electronic cards 3 are, for example, guided in a groove of the housing.

The minimal and maximum spacings between the electronic cards 3 are formed, for example in accordance with FIG. 6, by elongate holes in the electronic cards 3 and in the mechanical connection element 6 that is not variable in length, with the mechanical connection element 6 being connected by pins to the elongate holes of the electronic card 3. The elongate hole together with the pin of the mechanical connection element 6 defines the minimal and maximum spacings of the electronic cards 3.

### REFERENCE NUMERALS

2 light curtain
3 electronic card
3.1 first electronic card
3.2 last electronic card
4 light transmitter
5 light receiver
6 mechanical connection element
7 housing
8 housing end
10 spring element
11 light beams
12 objects
14 transmission unit
15 reception unit
16 conveyor belt

1. A light curtain having at least two electronic cards which are arranged behind one another in a longitudinal direction and on which a plurality of light transmitters and/or light receivers are arranged in series, wherein the electronic cards are each connected to one another by a mechanical connection element and the electronic cards are held in a housing; and wherein the housing is formed as a profile housing,
characterized in that
the first electronic card and the last electronic card are fixed to the respective housing end in the longitudinal direction so that the last light transmitter and/or light receiver of the first electronic card and of the last electronic card, said last light transmitter and/or light receiver being located at the housing end, has a fixed defined spacing from the housing end, with the connection element bounding a minimal spacing and a maximum spacing between the electronic cards, with the maximum spacing being greater than the minimal spacing.

2. A light curtain in accordance with claim 1, wherein the connection element is connected to the electronic card in one piece.

3. A light curtain in accordance claim 1, wherein the connection element has at least one spring element.

4. A light curtain in accordance with claim 1, wherein the connection element has at least two spring elements, with the spring elements having different spring constants.
